(19) United States
(12) Patent Application Publication
(10) Pub. No.: US 2026/0031170 A1
(43) Pub. Date: Jan. 29, 2026

(54) MITIGATING DATA DECODING FAILURES USING DATA LOGS

(71) Applicant: Microchip Technology Incorporated, Chandler, AZ (US)

(72) Inventors: Saswati DAS, Milpitas, CA (US); Nian Niles YANG, Mountain View, CA (US); Srinivas YELISETTI, Fremont, CA (US)

(21) Appl. No.: 19/173,808

(22) Filed: Apr. 8, 2025

Related U.S. Application Data
(60) Provisional application No. 63/675,738, filed on Jul. 26, 2024.

(51) Int. Cl. G11C 29/18; G06F 12/02

(52) U.S. Cl. CPC G11C 29/18; G06F 12/0246; G06F 2212/7205

(57) ABSTRACT

In some implementations, a controller may detect a failure associated with data obtained, using a first physical address, from a current physical location of a non-volatile memory device. The controller may determine, based on detecting the failure, a virtual block number based on the first physical address. The controller may determine that the virtual block number identifies a garbage collection block. The controller may determine a virtual wordline of the garbage collection block. The controller may obtain, from the virtual wordline, a data log that identifies a second physical address for a previous physical location of the data. The controller may obtain, using the second physical address, the data from the previous physical location.

### RELATED APPLICATION

This application claims priority to U.S. Provisional Patent Application No. 63/675,738 entitled “MITIGATING DATA DECODING FAILURES USING DATA LOGS,” filed Jul. 26, 2024, which is incorporated herein by reference in its entirety.

### FIELD

The present disclosure generally relates to reducing an uncorrectable bit error rate (UBER) of a solid state drive (SSD) and, for example, to mitigating the UBER using data tracking logs for reclaimed virtual blocks.

### BACKGROUND

Solid State Drives (SSDs) have revolutionized data storage technology, offering significant improvements in speed, reliability, and energy efficiency compared to traditional hard disk drives. SSDs utilize NAND flash memory, a type of non-volatile storage technology that retains data even when power is removed. This characteristic makes NAND flash memory ideal for portable devices and data centers alike, where data integrity and quick access are paramount.

NAND flash memory is composed of memory cells arranged in a grid-like structure. These cells store data by trapping electrical charges, with the presence or absence of charge representing binary data. Modern NAND flash memory may use multiple bits per cell, such as in Single-Level Cell (SLC), Multi-Level Cell (MLC), Triple-Level Cell (TLC), or Quad-Level Cell (QLC) configurations. This multi-level approach allows for higher storage densities, albeit at the cost of increased complexity in read and write operations.

SSDs incorporate NAND flash memory chips (referred to herein as “flash memory devices”) along with a controller that manages various operations, including data read/write, wear leveling, and error correction. The controller facilitates optimizing the performance and longevity of the SSD by distributing write operations evenly across the drive, a process known as wear leveling. This helps to prevent premature failure of individual memory cells due to excessive use.

As NAND flash memory cells age or experience repeated program/erase cycles, they may become less reliable, potentially leading to data errors. To mitigate this issue, SSDs employ various error correction techniques, such as Error Correction Code (ECC) and Low-Density Parity-Check (LDPC) codes. These mechanisms help to detect and correct bit errors, ensuring data integrity. However, as the NAND flash memory ages further, more sophisticated techniques may be necessary to maintain the drive's reliability and performance.

NAND flash memory devices may be organized into hierarchical structures to facilitate efficient data management and access. At the highest level, a flash memory device may be divided into one or more planes, which are independent units that can operate in parallel to improve performance. Each plane may contain multiple blocks, which are the basic units for erase operations in NAND flash memory.

Blocks are further subdivided into wordlines (or physical wordlines), which are groups of memory cells that share a common control gate. Wordlines are typically programmed together as a unit. Each wordline may contain one or more pages, which are the smallest addressable units for read operations. The size of a page may vary depending on the specific NAND flash memory architecture, but it is often in the range of 2 to 16 kilobytes. The term “wordline” (as used herein alone or individually) may be used to refer to a physical wordline. In contrast, the term “virtual wordline” may be used to refer to a logical construct that spans multiple physical wordlines, which can contain multiple physical pages.

To enhance performance and manage data across multiple flash memory devices, SSDs may implement the concept of virtual blocks. A virtual block (VB) is a logical construct that spans multiple physical blocks across different logical unit numbers (LUNs). LUNs are individual addressable units within a NAND flash memory device, and multiple LUNs may be present in a single device. By grouping physical blocks from different LUNs into a VB, the SSD controller can perform operations such as garbage collection and wear leveling more efficiently across the entire drive.

In some cases, a VB has a size that varies according to number of bad blocks. For example, if there are no bad blocks, the size=(#Channels)×(#Targets)×(#LUNs)×(Physical Block Size). A VB may include multiple virtual pages. A virtual page is a collection of pages across all LUNs in a VB. Typically, a reliability of the SSD decreases as the age of the non-volatile memory device increases. The decrease in reliability leads to an increase in read errors.

### SUMMARY

A method comprising: detecting a failure associated with data obtained, using a first physical address, from a current physical location of a non-volatile memory device; determining, based on detecting the failure, a virtual block number based on the first physical address; determining that the virtual block number identifies a garbage collection block; determining a virtual wordline of the garbage collection block; obtaining, from the virtual wordline, a data log that identifies a second physical address for a previous physical location of the data; and obtaining, using the second physical address, the data from the previous physical location.

A system comprising: a controller to: detect a decoding failure associated with data obtained, using a first physical address, from a current physical location of a non-volatile memory device, wherein the data is obtained based on a read retry operation associated with the first physical address, and wherein the data is obtained from a block of the non-volatile memory device; determine that the block is a garbage collection block; determine a second physical address of a previous physical location of the data, wherein the second physical address is determined using information regarding the garbage collection block; and perform a read operation using the second physical address.

A non-transitory computer-readable medium storing a set of instructions, the set of instructions comprising: one or more instructions that, when executed by one or more processors of a controller, cause the controller to: detect a decoding failure associated with data obtained, using a first physical address, from a current physical location of a non-volatile memory device, wherein the data is from a block of the non-volatile memory device; determine that the block is a garbage collection block; determine a second physical address of a previous physical location of the data, wherein the second physical address is determined using information from a virtual wordline of the garbage collection block; and perform a read operation using the second physical address.

### BRIEF DESCRIPTION OF THE DRAWINGS

FIG. 1 is a diagram of an example solid state drive (SSD) memory system as described herein.

FIG. 2 is a diagram of an example device associated with an SSD as described herein.

FIGS. 3A and 3B are diagrams of an example of a virtual wordline with a data tracking log as described herein.

FIG. 4 is a diagram of an example of a configuration with multiple garbage collection blocks as described herein.

FIG. 5 is a diagram of an example process associated with a read operation as described herein.

FIG. 6 is a diagram of example components of a storage device described herein.

FIG. 7 is a flowchart of an example process associated with mitigating data decoding failures as described herein.

### DETAILED DESCRIPTION

The following detailed description of example implementations refers to the accompanying drawings. The same reference numbers in different drawings may identify the same or similar elements.

A solid state drive (SSD) may provide data regarding the SSD to a host device associated with the SSD. As indicated above, an SSD may include multiple non-volatile memory devices. Blocks, of the multiple non-volatile memory devices (or dies of the multiple non-volatile memory devices), may form a virtual block (VB). The VB is a collection of blocks (e.g., memory blocks) across multiple logical unit numbers (LUNs). As used herein, a “block” is used to refer to a physical block. A physical block may be part of (or, in other words, may be included in) a virtual block.

Blocks, in the VB, may have the same program/erase (P/E) cycles. A controller of the SSD may maintain separate pools of VB for user data and system data. System data may be stored on Single-Level Cell (SLC) blocks due to the high reliability requirement for the system data whereas user data may be stored on Triple-Layer Cell (TLC) blocks. Some blocks may be reserved per die to be replacements for bad blocks. Typically, a reliability of the SSD decreases as the age of the non-volatile memory device increases. The decrease in reliability leads to an increase in read errors.

Currently an error correction code (ECC) correction rate (CR) of a low-density parity-check (LDPC) hard decoder is around 0.9%. But an uncorrectable bit error rate (UBER) for the SSD drive may be significantly higher, typically <1 sector per 10\hat{ }17 bits read. To achieve a desired correction rate, sometimes a controller (e.g., firmware) may perform operations such as read retry, threshold voltage (Vth) tracking, soft LDPC decoding, and/or a redundant array of independent disks (RAID) recovery procedure to find the correct read threshold voltage. Such operations not only increase read latency but also can cause read disturb on surrounding pages due to repetitive reads on a target page. Typically, predictable read latency is desired by end users of the SSD. The read disturb degrades the reliability of the semiconductor device.

Implementations described herein are directed to a technical solution to the technical problem of achieving predictable read latency. Additionally, implementations described herein are directed to a technical solution to the technical problem of reducing the UBER of the SSD. In this regard, the technical solution includes a method to keep track of an older location of the data and, in case of reclaimed data, to retrieve the data from the older location in the event of repetitive ECC decoding failures in a current physical location during read retry operations. In some examples, “reclaimed data” may refer to data that is deemed corrupted/unreadable after an error correction operation is performed on the data. In some examples, “reclaimed data” may include data that was cleaned up (or deleted) as part of a garbage collection operation. The garbage collection operation may have been performed because the data may have become obsolete (e.g., user data that is not frequently accessed by the host). An older version of the data may be re-used and thus reclaimed, in the event a current version of the data (requested by the host) is not readable. In some examples, “reclaimed data” may refer to data that has been recovered from a particular block considered unusable. For example, the data may be moved from the particular block to another block prior to the particular block being scheduled for a garbage collection operation.

For example, implementations described herein are directed to a method of tracking a previous location of garbage collection (GC) data and reading the data from the previous location in the event a read operation, on a current location of the data, causes ECC decoding failures which cannot be recovered using read retry operations (e.g., using read retry voltage shift values). Some implementations described herein improve read latency (QoS) by generating and storing data logs (also referred to as data tracking logs) for reclaimed virtual blocks. In some examples, the “reclaimed virtual block” may include a garbage collection virtual block with a same or older version of data in a current virtual block. In some examples, a “reclaimed virtual block” may refer to a virtual block that is being used to store data after previously being scheduled for a garbage collection operation. In some examples, one or more remedial actions may be performed on the reclaimed virtual block to enable the reclaimed virtual block to be used to store after previously being scheduled for a garbage collection operation.

The data logs may be included on garbage collection blocks containing cold data. In some examples, the data logs may be included at the end of a virtual wordline, of a garbage collection block, before parity pages of RAID. In some examples, “cold data” may refer to data that is old and has not been accessed for a threshold amount of time. A data log will record a prior physical address of a reclaimed data frame in the virtual wordline and use the prior physical address to read the data in the event of read retry attempts failing to recover the data in a current virtual block. As used herein, a “garbage collection block” may be used to refer to a block scheduled for a garbage collection operation.

A garbage collection operation is a process used to manage and optimize the storage space within the drive. In NAND flash memory, data cannot be directly overwritten; instead, it must be erased before new data can be written to the same location. Erase operations may occur on a block as a whole whereas write operations may occur on one or more wordlines. Garbage collection is the mechanism by which an SSD identifies and consolidates valid data from multiple blocks (mostly storing invalid data) into new blocks, allowing the old blocks to be erased and reused for future write operations.

The garbage collection process may involve copying valid data from multiple blocks (mostly storing invalid data) to a new block, then erasing the original blocks. In some examples, the blocks may be referred to as fragmented blocks. A fragmented block may refer to a fully filled block that includes data unused by a host. This operation frees up space and helps maintain the SSD's write performance over time. Garbage collection may be triggered when the number of free blocks falls below a certain threshold or during periods of low drive activity. By efficiently managing the available storage space and reducing fragmentation, garbage collection facilitates maintaining the overall performance and longevity of SSDs.

In some examples, during a garbage collection operation, a controller of the SSD may keep track of an older location of reclaimed data using a data log. The data log may be placed at the end of a programmed virtual wordline. In some situations, to avoid data retention issues on the reclaimed data in an older garbage collection block, a dummy refresh read may be performed on the older garbage collection block. The older garbage collection block may be in a free state. In other words, data of the older garbage collection block may be deleted because the data is unused by a host. As used herein, a “garbage collection block” may refer to a block scheduled for a garbage collection operation. In this regard, an “older garbage collection block” may refer to a block that has been scheduled for a garbage collection operation for a period of time. As used herein, a “dummy refresh read” may refer to a read operation, not initiated by a host device, that is performed to maintain data integrity. In some situations, a garbage collection operation, for a given block, may be performed multiple times. Accordingly, the SSD may include multiple copies of data with different timestamps, While the multiple copies of the data are unknown to the host, the multiple copies of the data are known to the SSD (e.g., a controller of the SSD). In this regard, as described herein, the controller may use one or more of the multiple copies of the data to recover the data requested by the host, in the event a current copy of the data has become unreadable. In some implementations, the controller may maintain, in a virtual block information table, information for different virtual blocks. For example, the information may indicate whether a virtual block is a host write block or a GC block. As used herein, a “host write block” (or “host block”) may refer to a virtual block that stores data received from a host device.

Implementations described herein reduce the overall UBER of the SSD and improve device reliability of the SSD. These implementations may reduce read latencies and improve QoS of the drive by avoiding triggering heroic data recovery procedures when another copy of data is available. Heroic data recovery procedures are used in an attempt to recover data when the level of data corruption is too great for standard data recovery techniques to be successful. As used herein, “heroic data recovery” refers to measures above and beyond standard data recovery techniques such as ECC. Heroic data recovery techniques are also typically much more time intensive than standard recovery techniques. An example of a heroic data recovery technique includes retrying a read operation one or more times using adjusted voltage reference values. Other examples of heroic data recovery techniques include Single Bit Soft Bit Error Recovery (SBSBER) methods with multiple soft-bit and hard-bit attempts. Generally, heroic data recovery techniques take longer and utilize more computational resources than standard data recovery methods and are often unsuccessful. Hence, employing heroic data recovery techniques can often be a waste of time and resources. Implementations described herein enhance drive life by reducing read disturb on a target page and neighboring pages caused by repetitive reads on erroneous pages. The repetitive reads may be from state-of-the-art heroic data recovery mechanisms.

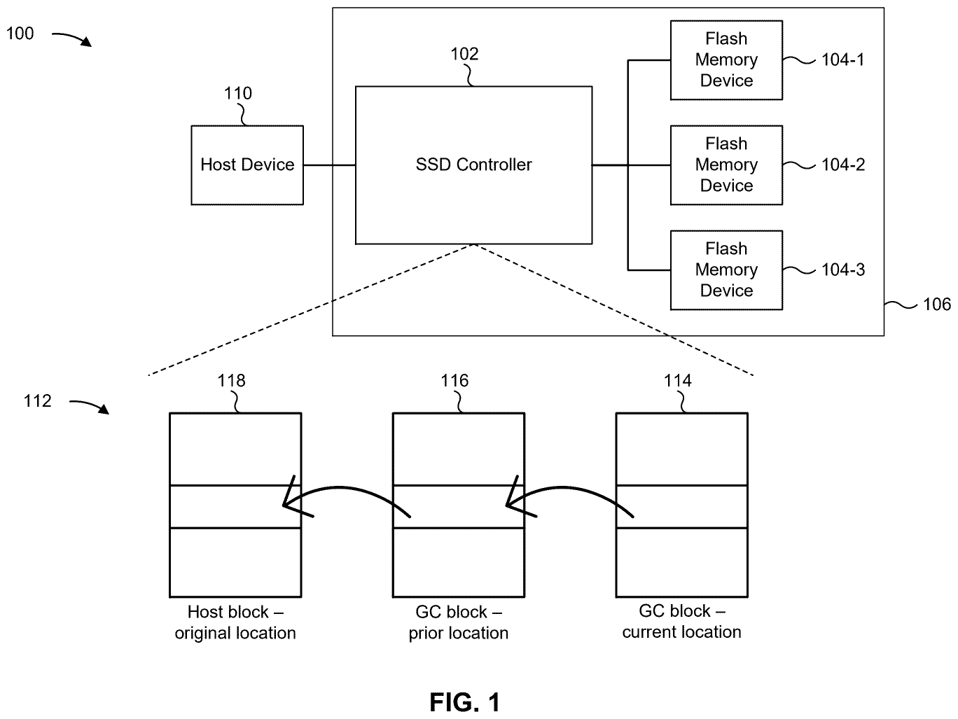

FIG. 1 illustrates a block diagram of a system 100 for managing data in a solid-state drive (SSD). The system 100 may include an SSD controller 102 connected to multiple flash memory devices 104-1, 104-2, and 104-3. The SSD controller 102 and the multiple flash memory devices 104-1, 104-2, and 104-3 may be included in an SSD 106. The SSD controller 102 may also be connected to a host device 110, which can send read and write commands to the SSD. This configuration allows for efficient data management and improved reliability in non-volatile memory systems.

The system 100 incorporates a data tracking mechanism, shown in example 112. This mechanism involves three blocks representing different stages of data storage: a GC block current location 114, a GC block prior location 116, and a host block original location 118. These blocks illustrate the potential movement of data through the system during garbage collection operations.

The GC block current location 114 may represent the most recent location where data has been stored after a garbage collection operation. In some cases, this location may be associated with a first physical address from which data is obtained. The GC block current location 114 may be part of a garbage collection block, which may be a virtual block scheduled for a garbage collection operation or a virtual block that is to store data of another block scheduled for a garbage collection operation.

The GC block prior location 116 may indicate a previous location of the data before it was moved during garbage collection. This location may be associated with a second physical address for a previous physical location of the data. The system 100 may use this information to retrieve data from the previous location in the event of repetitive ECC decoding failures in the current physical location during read retry operations.

The host block original location 118 may show the initial location where the data was first written by the host device 110. This location may represent the starting point of data movement through the system. In some implementations, the system 100 may track the movement of data from the host block original location 118 to the GC block prior location 116, and then to the GC block current location 114, among other locations, during successive garbage collection operations. In other words, the system 100 may track an entire chain of locations.

The SSD controller 102 may manage these data movements and maintain information about the current and previous locations of data. This allows the controller to potentially retrieve data from a previous location if a read operation fails at the current location, improving data reliability and recovery capabilities of the system 100. The controller may detect a failure associated with data obtained from the current physical location and determine a virtual block number based on the second physical address.

In some implementations, the SSD controller 102 may determine that the virtual block number identifies a garbage collection block. The controller may also determine that the previous location of the data in the prior garbage collection block or a host write block has not been overwritten. This determination may be crucial for ensuring that the data in the previous location is still valid and can be used for recovery purposes.

The system 100 may utilize a virtual wordline structure to organize and manage data within the flash memory devices. The SSD controller 102 may determine a virtual wordline of the garbage collection block and obtain a data log from this virtual wordline. The data log may identify the second physical address for the previous physical location of the data. This mechanism allows the system to track the movement of data across different garbage collection cycles and facilitates efficient data recovery when needed.

By implementing this data tracking mechanism, the system 100 provides a technical solution to the problem of achieving predictable read latency and reducing the uncorrectable bit error rate (UBER) of the SSD. The system can retrieve data from older locations in case of reclaimed data, mitigating the impact of repetitive ECC decoding failures in the current physical location during read retry operations. This approach may improve read latency and quality of service (QoS) by avoiding the need to trigger heroic data recovery procedures when another copy of data is available.

The system 100 offers several advantages over conventional SSD systems. It may reduce overall UBER and improve device reliability by providing an additional layer of data recovery. The system may also enhance drive life by reducing read disturb on target pages and neighboring pages caused by repetitive reads on erroneous pages. These benefits contribute to the overall performance and longevity of the SSD, making it a more robust and reliable storage solution for various applications.

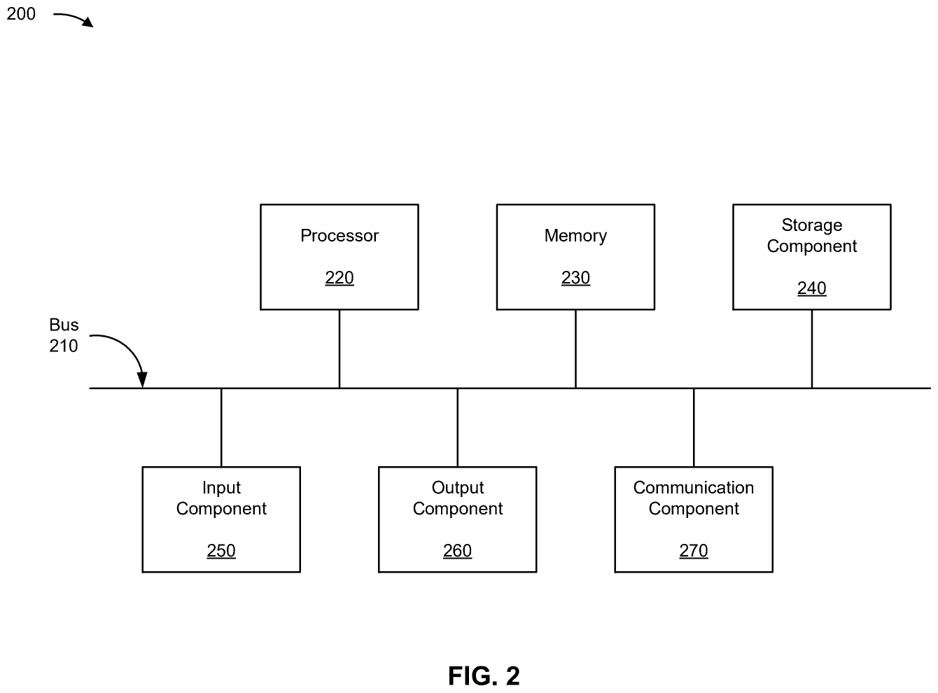

FIG. 2 is a diagram of example components of a device 200, in accordance with the present disclosure. The device 200 may be similar to, include, or be included in, the host device 110 or the SSD controller 102 shown in FIG. 1, the flash memory device 104 shown in FIG. 1, the flash memory device 106 shown in FIG. 1, and/or the flash memory device 108 shown in FIG. 1, among other examples. The device 200 may be used to implement any one or more aspects of the techniques, processes, and/or apparatuses described herein. In some implementations, the device 200 may refer to one or more devices 200 and one or more components of the device 200. As shown in FIG. 2, the device 200 may include a bus 210, a processor 220, a memory 230, a storage component 240 (which may be an SSD), an input component 250, an output component 260, and a communication component 270. The device 200 may be, for example, a computing device.

The bus 210 includes a component that enables wired or wireless communication among the components of the device 200. The processor 220 may be a central processing unit, a graphics processing unit, a microprocessor, a controller, a microcontroller, a digital signal processor, an FPGA, an ASIC, or another type of processing component. The processor 220 is implemented in hardware, firmware, or a combination of hardware and software. In some implementations, the processor 220 includes one or more processors capable of being programmed to perform a function. The memory 230 includes a random access memory, a read only memory, or another type of memory (e.g., a flash memory, a magnetic memory, or an optical memory).

The storage component 240 stores information or software related to the operation of the device 200. For example, the storage component 240 may include a hard disk drive, a magnetic disk drive, an optical disk drive, a solid state disk drive, a compact disc, a digital versatile disc, or another type of non-transitory computer-readable medium. The input component 250 enables the device 200 to receive input, such as user input or sensed inputs. For example, the input component 250 may include a touch screen, a keyboard, a keypad, a mouse, a button, a microphone, a switch, a sensor, a global positioning system component, an accelerometer, a gyroscope, or an actuator. The output component 260 enables the device 200 to provide output, such as via a display, a speaker, or one or more light-emitting diodes. The communication component 270 enables the device 200 to communicate with other devices, such as via a wired connection or a wireless connection. For example, the communication component 270 may include a receiver, a transmitter, a transceiver, a modem, a network interface card, or an antenna.

The device 200 may perform one or more processes described herein. For example, a non-transitory computer-readable medium (e.g., the memory 230 or the storage component 240) may store a set of instructions (e.g., one or more instructions, code, software code, or program code) for execution by the processor 220. In some cases, a number of processors 220 may perform a process in parallel. In some cases, one or more processors 220 may perform one or more aspects of a process while one or more other processors 220 may perform one or more other aspects of the process. Similarly, instructions may be duplicated, distributed, and/or partitioned across two or more memories 230. In some implementations, hardwired circuitry may be used instead of or in combination with the instructions to perform one or more processes described herein. Thus, implementations described herein are not limited to any specific combination of hardware circuitry and software.

The number and arrangement of components shown in FIG. 2 are provided as an example. The device 200 may include additional components, fewer components, different components, or differently arranged components than those shown in FIG. 2. For example, the processor 220 may refer to two or more processors and the memory 230 may refer to two or more memories 230. Additionally, or alternatively, a set of components (e.g., one or more components) of the device 200 may perform one or more functions described as being performed by another set of components of the device 200.

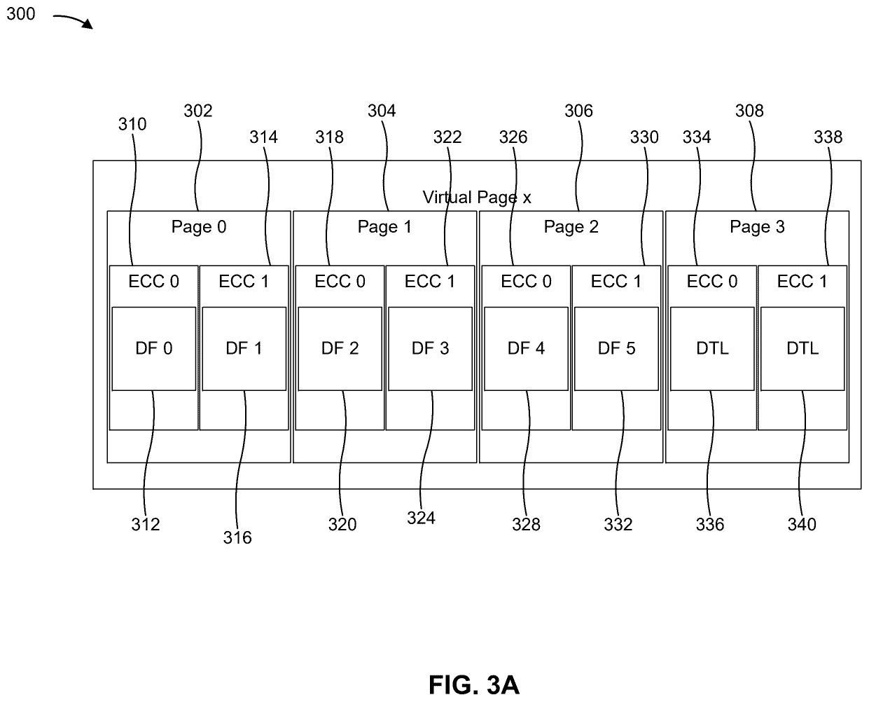

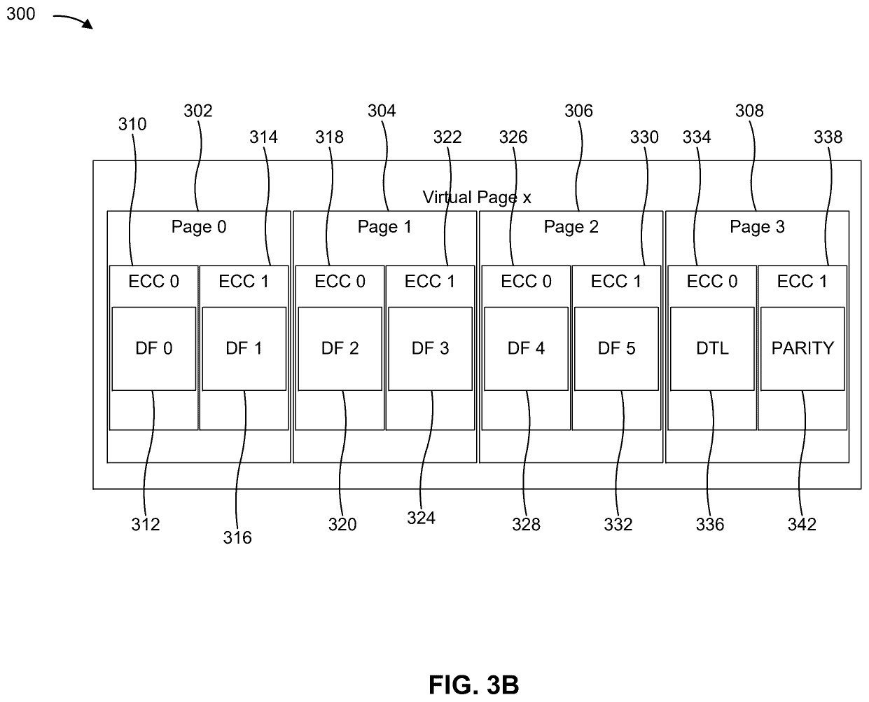

FIGS. 3A and 3B are diagrams of an example of a virtual wordline 300 with a data tracking log as described herein. As shown in FIG. 3A, the virtual wordline 300 may include a data tracking log (also referred to as “data log”). For example, as shown in FIG. 3, one or more data frames may include the data tracking log. As shown in FIG. 3A, “DF” may be used to refer to a data frame and “DTL” may be used to refer to a data tracking log.

The virtual wordline 300 may be composed of multiple flash pages, including flash page 0 302, flash page 1 304, flash page 2 306, and flash page 3 308. Each flash page may contain multiple components organized in a specific layout to facilitate efficient data storage, error correction, and data tracking.

In some implementations, a flash page may refer to a minimum addressable unit for read and write operations in a NAND flash memory device. The size of a flash page may vary depending on the specific NAND flash memory architecture, but it is often in the range of 2 to 16 kilobytes. For example, flash page 0 302 may have a size of 8 kilobytes and may include multiple data frames and ECC chunks.

Each flash page in the virtual wordline 300 may be divided into multiple ECC chunks and data frames. An ECC chunk may refer to a portion of data associated with error correction code information. For instance, flash page 0 302 includes ECC chunk 0 310 and data frame 0 312, followed by ECC chunk 1 314 and data frame 1 316. This pattern may be repeated in subsequent flash pages, such as flash page 1 304, which contains ECC chunk 0 318 and data frame 2 320, along with ECC chunk 1 322 and data frame 3 324.

The data frames (e.g., data frame 0 312, data frame 1 316, data frame 2 320, data frame 3 324) may store user data or system data. In some aspects, a data frame may refer to a logical unit of data that is managed by the SSD controller. The size of a data frame may vary depending on the specific implementation, but it may typically range from 512 bytes to 4 kilobytes. For example, data frame 0 312 may have a size of 2 kilobytes and may contain user data written by a host device.

The ECC chunks (e.g., ECC chunk 0 310, ECC chunk 1 314, ECC chunk 0 318, ECC chunk 1 322) may contain error correction code information for the corresponding data frames. In some implementations, an ECC chunk may refer to a portion of data that includes parity bits or other error correction information. The ECC chunks may be used by the SSD controller to detect and correct errors that may occur during read operations. For instance, ECC chunk 0 310 may contain error correction information for data frame 0 312, allowing the controller to correct a certain number of bit errors that may occur in the data frame.

Flash page 2 306 follows a similar pattern to the previous flash pages, with ECC chunk 0 326 and data frame 4 328, as well as ECC chunk 1 330 and data frame 5 332. However, the structure of flash page 3 308 differs slightly from the other flash pages in the virtual wordline 300. Flash page 3 308 contains ECC chunk 0 334 followed by a data tracking log 336, and ECC chunk 1 338 paired with another data tracking log 340.

The data tracking logs (e.g., data tracking log 336, data tracking log 340) may store information about previous physical locations of data. In some aspects, a data tracking log may refer to a data structure that contains metadata about the history of data movement within the SSD. For example, data tracking log 336 may include information such as a previous physical address, a timestamp, and a virtual block number associated with a particular data frame. This information can be used for data recovery purposes, especially in cases where a read operation fails at the current physical location of the data.

In some implementations, as shown in FIG. 3A, the data tracking logs may be placed at the end of a programmed virtual wordline, as shown in flash page 3 308. This placement may allow for efficient access to the tracking information without interfering with the regular data storage pattern of the other flash pages. For instance, when a controller detects a failure associated with data obtained from a current physical location, it may access the data tracking log 336 or 340 to determine a previous physical location of the data. In some implementations, as shown in FIG. 3B, the data tracking log may be placed at the end of a programmed virtual wordline prior to parity bits 342.

The virtual wordline 300 structure may support various data management operations, including garbage collection. During a garbage collection operation, valid data from multiple blocks (mostly storing invalid or stale data) may be consolidated into new blocks, allowing the old blocks to be erased and reused. The data tracking logs 336 and 340 may play a crucial role in this process by maintaining a record of the data's previous locations, which can be used for data recovery if needed.

In alternative embodiments, the layout of the virtual wordline 300 may be modified to accommodate different storage requirements or error correction schemes. For example, the number of flash pages per virtual wordline may be increased or decreased, or the size and arrangement of ECC chunks and data frames may be adjusted. Additionally, the placement of data tracking logs within the virtual wordline may be altered, such as distributing them across multiple flash pages instead of concentrating them in the last flash page.

The structure of the virtual wordline 300 as described in this disclosure may provide several advantages for non-volatile memory systems. It may allow for efficient data storage and error correction while also incorporating a mechanism for tracking data movement history. This combination may enhance the overall reliability and performance of the storage system by enabling advanced data recovery techniques and optimizing garbage collection operations.

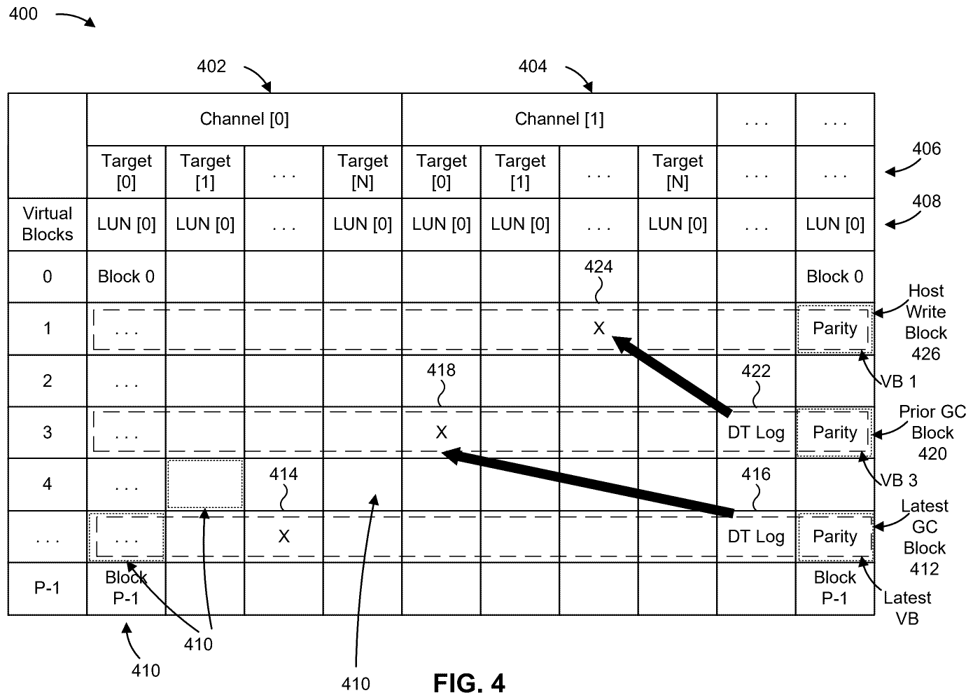

FIG. 4 is a diagram of an example of a configuration 400 with multiple garbage collection blocks as described herein. FIG. 4 illustrates the configuration 400 of a storage system that utilizes data tracking logs for managing garbage collection blocks in a non-volatile memory device, such as an SSD. The configuration 400 comprises multiple channels, represented by channel 402 and channel 404, which may facilitate parallel data transfer operations. Each channel is connected to multiple targets 406, which in turn are connected to multiple logical unit numbers (LUNs) 408, forming a hierarchical structure that allows for efficient data management and access.

The system is organized into blocks 410, which are arranged in a matrix across the channels, targets, and LUNs. In some implementations, a block may refer to a basic unit of erase operations in NAND flash memory. For example, a block may typically contain 128 or 256 pages, with each page capable of storing several kilobytes of data. The blocks 410 include different types of blocks, such as the latest GC block 412, prior GC block 420, and host write block 426, each serving specific purposes in the data management process. GC block 412, prior GC block 420, and/or host write block 426 may be virtual blocks.

As shown in FIG. 4, virtual block 1 (or garbage collection virtual block 1) and virtual block 3 (or garbage collection virtual block 3) may be in a free state. A latest virtual block (or latest garbage collection virtual block) may be in a ready state or a used state. A “latest virtual block” may refer to a virtual block that has recently been scheduled for garbage collection. For example, a “latest virtual block” may refer to a most recent virtual block scheduled for garbage collection. As shown in FIG. 4, the latest virtual block may include a first data tracking log 416 that identifies a first previous location of data. For example, the first data tracking log 416 may indicate that the data is stored on virtual block 3. The first data tracking log 416 may identify a physical location of the data on a wordline of a block included in virtual block 3. In some examples, the first data tracking log 416 may be included on a virtual wordline prior to parity bits (as shown in FIG. 3B, for example).

As shown in FIG. 4, virtual block 3 may include a second data tracking log 422 that identifies a second previous location of the data. For example, the second data tracking log 422 may indicate that the data is stored on virtual block 1. The second data tracking log 422 may identify a physical location of the data on a wordline of a block included in virtual block 1. In some examples, the second data tracking log 422 may be included on a virtual wordline prior to parity bits (as shown in FIG. 3B, for example).

The latest GC block 412 (which is a virtual block) contains a data tracking log 416, which stores information about the previous location of data. As used herein, a “data tracking log” may refer to a data structure that maintains metadata about the movement history of data within the storage system. The data tracking log 416 points to a location in the prior GC block 420, as indicated by the arrow. This mechanism allows the system to trace the history of data movement across different garbage collection cycles.

The prior GC block 420 also contains a data tracking log 422, which in turn points to a location in the host write block 426. This creates a chain of data tracking logs that can be used to trace the history of data movement across different blocks. For instance, if a read operation fails at the current location in the latest GC block 412, the system can use the data tracking log 416 to locate the data in the prior GC block 420, and if necessary, follow the chain further back via one or more intervening blocks to the host write block 426. In other words, the system may track an entirety of the chain.

Block 418 and block 424 represent intermediate blocks in the system, which may contain user data. Block 418 and block 424 may be data blocks subjected to the garbage collection process multiple times, resulting in multiple copies of the same user data. Locations of the multiple copies of the same user data may be tracked, using the data tracking logs, to enable a copy of the user data to be returned to the host when the host requests a current copy of the data that is unreadable. These blocks illustrate the dynamic nature of data storage in the system, where blocks may transition between different states (e.g., active, garbage collection, free) based on the ongoing data management operations.

The configuration 400 also includes parity information for each block, as shown in the rightmost column. This parity data provides error correction capabilities for the stored information. In some aspects, “parity information” may refer to additional data generated from the original data, which can be used to detect and correct errors that may occur during data storage or retrieval. For example, the parity information may be used in conjunction with RAID (Redundant Array of Independent Disks) techniques to enhance data reliability.

At the bottom of the diagram, a block labeled P−1 is shown to indicate the presence of additional blocks in the system beyond what is explicitly depicted. Accordingly, the configuration 400 is scalable and can accommodate a large number of blocks to meet various storage capacity requirements.

The use of data tracking logs in this configuration allows the system to efficiently manage data through multiple garbage collection cycles. Garbage collection, in the context of this disclosure, may refer to the process of identifying and consolidating valid data from multiple blocks (mostly storing invalid or stale data) into new blocks, allowing the old blocks to be erased and reused. This process is essential for maintaining the performance and longevity of the storage system.

In some implementations, the system may use the data tracking logs to optimize read operations. For example, if a read operation fails at the current location in the latest GC block 412, the controller may consult the data tracking log 416 to retrieve the data from its previous location in the prior GC block 420. This approach can potentially improve read latency and reduce the need for complex error recovery procedures.

Alternative embodiments of the configuration 400 may include variations in the structure and organization of the blocks. For instance, the number of channels, targets, or LUNs may be adjusted based on specific performance requirements or hardware constraints. Additionally, the system may implement different strategies for placing and managing data tracking logs, such as storing them in dedicated blocks or distributing them across multiple blocks for redundancy.

The configuration 400 may also support advanced features such as wear leveling and bad block management. Wear leveling may involve distributing write operations evenly across all blocks to prevent premature failure of frequently used blocks. Bad block management may include identifying and marking faulty blocks, and remapping their data to spare blocks to maintain data integrity and system reliability.

In summary, the configuration 400 illustrated in FIG. 4 demonstrates a sophisticated approach to data management in non-volatile memory systems. By incorporating data tracking logs and organizing blocks across multiple channels, targets, and LUNs, this configuration enables efficient garbage collection, improved data recovery capabilities, and enhanced overall system reliability. These features collectively contribute to the performance and longevity of the storage system, making it suitable for a wide range of applications that require high-performance and reliable data storage.

Table 1 shows an example of a data tracking log as described herein. In some implementations, the data tracking log may be stored in a virtual wordline of a garbage collection block. As shown in Table 1, the data tracking log may include metadata that includes information identifying the data tracking log. The data tracking log may include information identifying a physical address of the data.

TABLE 1
A diagram of an example of a data tracking log

| DT | | |
|---|---|---|
| log | | FW metadata (contains |
| (511 | | 0xFFFFFFF8 as special signature for DT |
| entries) | Reserved | log in place of LBA) |
| 4096 bytes | 64 bytes | 16 bytes |

The data tracking log may be used to determine a previous location of data requested by a host device. For example, when a read command is issued from the host device, a controller may read a current physical location (from logical to physical (L2P) table) and data may be obtained from the current physical location. The L2P mapping table may identify a physical address of the current physical location.

The data may be decoded. If the data encounters ECC decoding failures and if the decoding failures cannot be recovered using read retries, a controller may obtain a data tracking log from a current block storing the data and use the data tracking log to identify a garbage collection block for the data. If the controller identifies the GC block, then the controller may calculate a virtual wordline and read a data tracking log written towards the end of the virtual wordline before RAID parity information (e.g., RAID parity bits).

From the data tracking log, the controller may obtain a previous location of the data. If the previous location belongs to a prior GC block in a free state, the controller may determine that the prior GC block is in a free pool and may not have been recycled. In other words, the controller may determine that the prior GC block may not have been overwritten. Based on determining the prior GC block has not been overwritten, the controller may read a data frame from the previous location and compare a logical block address (LBA) from the metadata of the data frame and an LBA associated with the current physical location to ensure that the previous location has not been overwritten.

If the LBA from the metadata matches the LBA associated with the current physical location, the controller may read data from the previous location. If ECC decoding for the previous location fails, the controller may check if an earlier location (prior to the previous location) is a GC block and if so, the controller may repeat the prior operations until reaching good data or an original location (e.g., a host write block), or until the controller finds that the prior location is overwritten.

If the controller reaches an older GC block that is overwritten or reaches a host write block without success in recovering good data, the controller may proceed with initiating a heroic recovery process in the latest location of the data as pointed by L2P table.

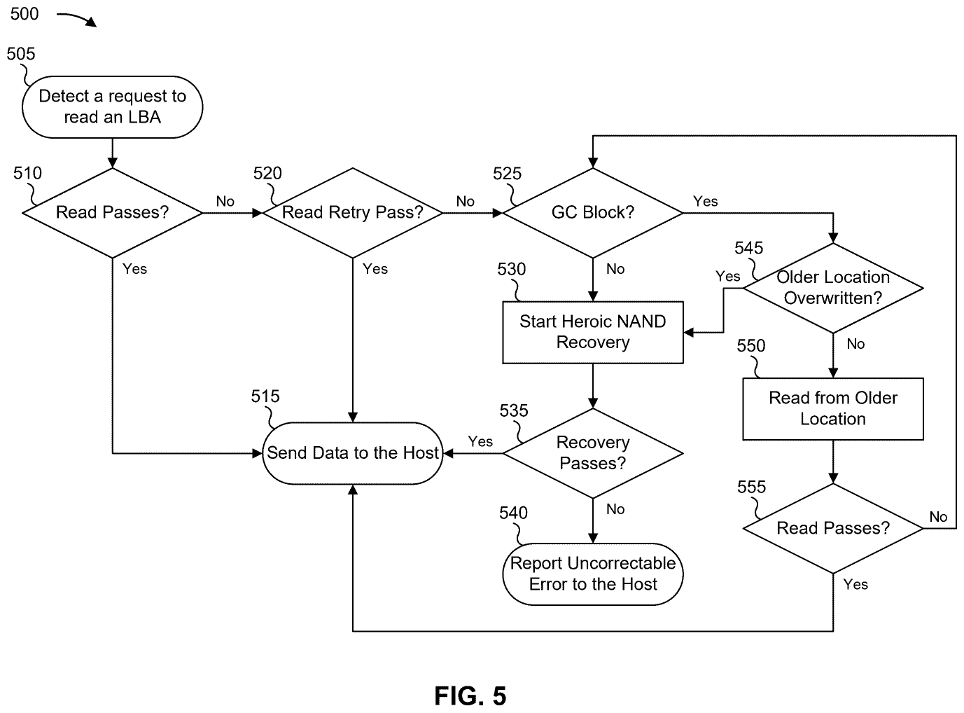

FIG. 5 is a diagram of an example process 500 associated with a read operation as described herein. In some examples, the read operation may be performed by a controller (e.g., SSD controller 102). The read operation may be performed based on a host device (e.g., host device 110) initiating a read operation. As shown in FIG. 5, process 500 may include detecting a request to read an LBA (block 505). For example, a host device may initiate the read operation to read the LBA. As shown in FIG. 5, process 500 may include determining if the read operation passes (block 510). For example, a controller may determine whether decoding of data, obtained based on the read operation, is successful.

As shown in FIG. 5, process 500 may include sending the data to the host device (block 515). For example, the data may be sent to the host device if the read operation passes. As shown in FIG. 5, process 500 may include determining if a read retry operation passes (block 520). The read retry operation may be performed if the read operation does not pass. If the read retry operation passes, the data may be sent to the host device.

As shown in FIG. 5, process 500 may include determining if a virtual block is a GC block (block 525). For example, if the read retry operation does not pass, the controller may determine if the virtual block, in which the data is included, is a GC block.

As shown in FIG. 5, process 500 may include starting a heroic data recovery operation (block 530). The heroic data recover operation may be initiated if the virtual block is not a GC block. As shown in FIG. 5, process 500 may include determining whether the heroic data recovery operation passes (block 535). If the heroic data recovery operation is successful, the data may be sent to the host device.

As shown in FIG. 5, process 500 may include reporting uncorrectable error to the host device (block 540). The uncorrectable error may be reported if the heroic data recovery operation is not successful.

As shown in FIG. 5, process 500 may include determining whether an older location has been overwritten (block 545). For example, if the controller determine that the virtual block is a GC block, the controller may determine whether an older location, identified by the GC block, has been overwritten. If the older location has been overwritten, the controller may initiate the heroic data recovery operation.

As shown in FIG. 5, process 500 may include reading from the older location (block 550). For example, the controller may read from the older location, if the older location has not been overwritten. As shown in FIG. 5, process 500 may include determining whether reading from the older location has passed (block 555). As shown in FIG. 5, process 500 may include sending the data to the host device (block 515). For example, the controller may send the data to the host device if reading from the older location has passed. If reading from the older location has not passed, the controller may identify a prior GC block that includes the data. As used herein, “reading” may refer to an entire read error handling process, which includes a read retry. In some implementations, a read retry may be performed prior to the controller identifying the prior GC block.

Although FIG. 5 shows example blocks of the process 500, in some implementations, the process 500 may include additional blocks, fewer blocks, different blocks, or differently arranged blocks than those depicted in FIG. 5. Additionally, or alternatively, two or more of the blocks of the process 500 may be performed in parallel.

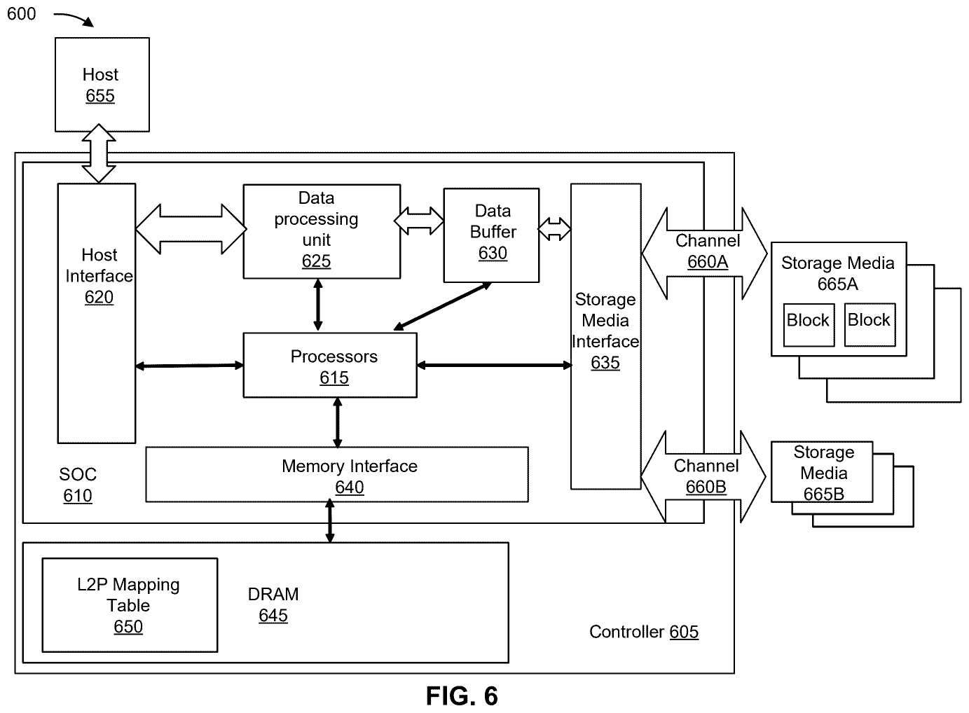

FIG. 6 is a diagram of example components of a storage device 600, which may correspond to one or more element of FIGS. 1-4. As shown in FIG. 6, the storage device 600 may include a controller 605 (e.g., an SSD controller). The controller 605 may include a system on chip (SOC) 610. The SOC 610 may perform computing or processing operations for the controller 605. The SOC 610 may include one or more processors 615 that control, command, or observe operations at one or more other components of the SOC 610. The one or more processors 615 may be communicably coupled to one or more of a host interface 620, a data processing unit (DPU) 625, a data buffer 630, a storage medium interface 635, or a memory interface 640.

The host interface 610 may be configured to communicate with a host device (e.g., host device 655 described below). The DPU 625 may include a functional block that is responsible for managing data operations, such as reading, writing, error correction, or formatting (e.g., data flow between a host interface and a storage medium). The DPU 625 may perform tasks such as page and block management (e.g., organization of data within storage media), bad block management, garbage collection, error correction and detection (e.g., using error correction codes or soft bit processing), data transformation (e.g., address mapping from host addresses to physical addresses, compression and decompression, or scrambling, among other examples), encryption and decryption, or power management associated with data operations, among other examples. The data buffer 630 may include a temporary storage area used to transfer or process data between the storage media and a host system. The data buffer 630 is a pipeline data buffer for the data transition. The memory interface 640 may provide an interface between the SOC 610 and the DRAM 645 to facilitate transfers of information. For example, the memory interface 640 (e.g., an interface between the controller and an external DDR or DRAM to temporarily hold the data) may support requests to access a logical to physical (L2P) mapping table to identify a physical location of data requested by the host device, or to provide mapping information for storage in the L2P mapping table.

The controller 605 may further include DRAM 645. The DRAM 645 may locally store information that is available on demand at the controller 605 for operations of the controller 605. For example, the DRAM 645 may store an L2P mapping table 650 that maps logical locations of data and physical locations of data on connected storage media. In this way, the controller 605 may have access to mapping information for locating data on the connected storage media based at least in part on an indication associated with host data when written.

The host interface 620 may provide an interface for communicating with a host 655. For example, the host interface 620 may receive an access request or data for storage on connected storage media. In some aspects, the host interface 620 may provide data to the host after reading the data on from the connected storage media.

The storage media interface 635 may communicate via one or more channels 660 (e.g., 660A and 660B) with one or more connected storage media 665 (e.g., 665A and 665B). For example, the controller 605 may perform or initiate a read or write operation at a physical location of a storage media 665.

The number and arrangement of components shown in FIG. 6 are provided as an example.

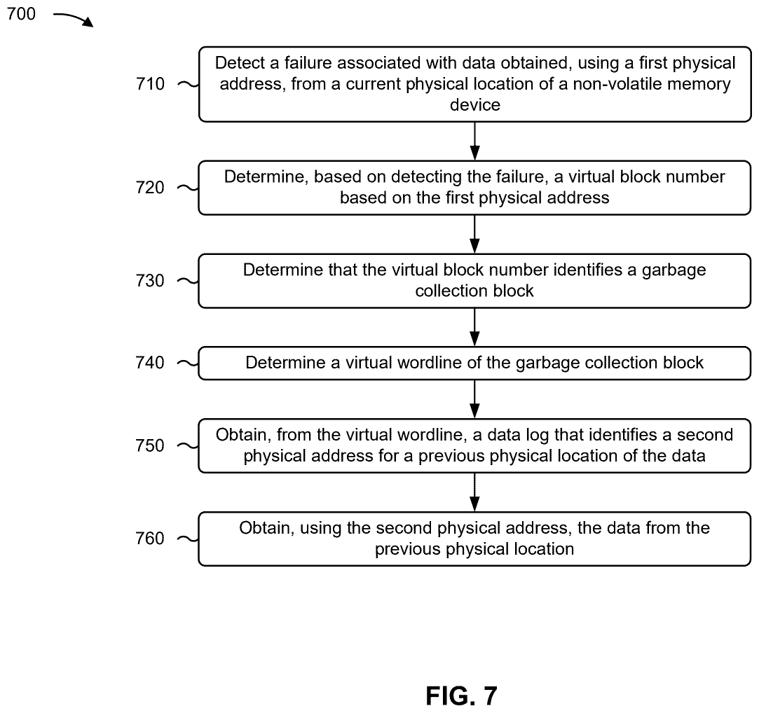

FIG. 7 is a flowchart of an example process 700 associated with mitigating data decoding failures. In some implementations, one or more process blocks of FIG. 7 may be performed by a controller of an SSD.

As shown in FIG. 7, process 700 may include detecting a failure associated with data obtained, using a first physical address, from a current physical location of a non-volatile memory device (block 710). For example, the controller may detect a failure associated with data obtained, using a first physical address, from a current physical location of a non-volatile memory device, as described above in connection with block 520.

As shown in FIG. 7, process 700 may include determining, based on detecting the failure, a virtual block number based on the first physical address (block 720). For example, the controller may determine, based on detecting the failure, a virtual block number based on the first physical address, as described above in connection with FIG. 1.

As shown in FIG. 7, process 700 may include determining that the virtual block number identifies a garbage collection block (block 730). For example, the controller may determine that the virtual block number identifies a garbage collection block, as described above in connection with blocks 525 and 545.

As shown in FIG. 7, process 700 may include determining a virtual wordline of the garbage collection block (block 740). For example, the controller may determine a virtual wordline of the garbage collection block, as described above in connection with FIG. 1.

As shown in FIG. 7, process 700 may include obtaining, from the virtual wordline, a data log that identifies a second physical address for a previous physical location of the data (block 750). For example, the controller may obtain, from the virtual wordline, a data log that identifies a second physical address for a previous physical location of the data, as described above in connection with FIGS. 1 and 4.

As shown in FIG. 7, process 700 may include obtaining, using the second physical address, the data from the previous physical location (block 760). For example, the controller may obtain, using the second physical address, the data from the previous physical location, as described above in connection with FIG. 1 and block 550.

In some implementations, detecting the failure comprises detecting a first decoding failure associated with performing a read operation using the physical address, and detecting a second decoding failure associated with performing a read retry operation using the physical address.

In some implementations, determining the virtual wordline comprises determining the virtual wordline using a logical unit number, a block number, and a page number, wherein the logical unit number, the block number, and the page number are identified by the first physical address.

In some implementations, the previous physical location is included in an additional block, and wherein obtaining the data from the previous physical location comprises determining whether the additional block has been overwritten, and obtaining, using the second physical address, the data from the previous physical location based on determining whether the block has been overwritten.

In some implementations, obtaining the data from the previous physical location comprises reading a data frame from the previous physical location, determining a logical block address (LBA) based on the data frame, determining whether the block has been overwritten based on the LBA, and obtaining, using the second physical address, the data from the previous physical location based on determining whether the block has been overwritten.

In some implementations, obtaining the data from the previous physical location comprises performing a comparison using the LBA to determine that the block has not been overwritten based on performing the comparison using the LBA, and obtaining, using the second physical address, the data from the previous physical location based on determining that the block has not been overwritten.

In some implementations, the process 700 includes storing the data log, in the virtual wordline, to identify the previous physical location of the data.

In some implementations, the process 700 includes performing a read refresh operation on the previous physical location after storing the data log in the virtual wordline, to identify the previous physical location of the data.

Although FIG. 7 shows example blocks of the process 700, in some implementations, the process 700 may include additional blocks, fewer blocks, different blocks, or differently arranged blocks than those depicted in FIG. 7. Additionally, or alternatively, two or more of the blocks of the process 700 may be performed in parallel.

In some implementations, a method comprises detecting a failure associated with data obtained, using a first physical address, from a current physical location of a non-volatile memory device; determining, based on detecting the failure, a virtual block number based on the first physical address; determining that the virtual block number identifies a garbage collection block; determining a virtual wordline of the garbage collection block; obtaining, from the virtual wordline, a data log that identifies a second physical address for a previous physical location of the data; and obtaining, using the second physical address, the data from the previous physical location.

In some implementations, a system comprises a controller to: detect a decoding failure associated with data obtained, using a first physical address, from a current physical location of a non-volatile memory device, wherein the data is obtained based on a read retry operation associated with the first physical address, and wherein the data is obtained from a block of the non-volatile memory device; determine that the block is a garbage collection block; determine a second physical address of a previous physical location of the data, wherein the second physical address is determined using information regarding the garbage collection block; determine that the second physical address is not overwritten; and perform a read operation using the second physical address.

In some implementations, a non-transitory computer-readable medium storing a set of instructions includes one or more instructions that, when executed by one or more processors of a controller, cause the controller to: detect a decoding failure associated with data obtained, using a first physical address, from a current physical location of a non-volatile memory device, wherein the data is from a block of the non-volatile memory device; determine that the block is a garbage collection block; determine a second physical address of a previous physical location of the data, wherein the second physical address is determined using information from a virtual wordline of the garbage collection block; determine that the second physical address is not overwritten; and perform a read operation using the second physical address.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

As used herein, the term “component” is intended to be broadly construed as hardware, firmware, or a combination of hardware and software. It will be apparent that systems or methods described herein may be implemented in different forms of hardware, firmware, or a combination of hardware and software. The actual control hardware or software code used to implement these systems or methods is not limiting of the implementations. Thus, the operation and behavior of the systems or methods are described herein without reference to specific software code—it being understood that software and hardware can be used to implement the systems or methods based on the description herein.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Although particular combinations of features are recited in the claims or disclosed in the specification, these combinations are not intended to limit the disclosure of various implementations. In fact, many of these features may be combined in ways not specifically recited in the claims or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein is to be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “or,” unless explicitly stated otherwise (e.g., if used in combination with “either” or “only one of”).

What is claimed is:

1. A method comprising:
detecting a failure associated with data obtained, using a first physical address, from a current physical location of a non-volatile memory device;
determining, based on detecting the failure, a virtual block number based on the first physical address;
determining that the virtual block number identifies a garbage collection block;
determining a virtual wordline of the garbage collection block;
obtaining, from the virtual wordline, a data log that identifies a second physical address for a previous physical location of the data; and
obtaining, using the second physical address, the data from the previous physical location.

2. The method of claim 1, wherein detecting the failure comprises:
detecting a first decoding failure associated with performing a read operation using the physical address; and
detecting a second decoding failure associated with performing a read retry operation using the physical address.

3. The method of claim 1, wherein determining the virtual wordline comprises:
determining the virtual wordline using a logical unit number, a block number, and a page number, wherein the logical unit number, the block number, and the page number are identified by the first physical address.

4. The method of claim 1, wherein the previous physical location is included in a block, and wherein obtaining the data from the previous physical location comprises:
determining whether the block has been overwritten; and
obtaining, using the second physical address, the data from the previous physical location based on determining whether the block has been overwritten.

5. The method of claim 4, wherein obtaining the data from the previous physical location comprises:
reading a data frame from the previous physical location;
determining a logical block address (LBA) based on the data frame;
determining whether the block has been overwritten based on the LBA; and
obtaining, using the second physical address, the data from the previous physical location based on determining whether the block has been overwritten.

6. The method of claim 5, wherein obtaining the data from the previous physical location comprises:
performing a comparison using the LBA and an LBA associated with a current physical location of the data;
determining that the block has not been overwritten based on performing the comparison using the LBA and the LBA associated with the current physical location of the data; and
obtaining, using the second physical address, the data from the previous physical location based on determining that the block has not been overwritten.

7. The method of claim 1, comprising, prior to detecting the failure, storing the data log, in the virtual wordline, to identify the previous physical location of the data.

8. The method of claim 7, comprising storing the data log, in the virtual wordline, prior to parity bits.

9. A system comprising:
a controller to:
detect a decoding failure associated with data obtained, using a first physical address, from a current physical location of a non-volatile memory device, wherein the data is obtained based on a read retry operation associated with the first physical address, and wherein the data is obtained from a block of the non-volatile memory device;
determine that the block is a garbage collection block;
determine a second physical address of a previous physical location of the data, wherein the second physical address is determined using information regarding the garbage collection block; and
perform a read operation using the second physical address.

10. The system of claim 9, wherein, to determine the second physical address, the controller is to:
determine a virtual wordline using a logical unit number, a block number, and a page number, wherein the logical unit number, the block number, and the page number are identified by the first physical address; and
determine the second physical address using the virtual wordline.

11. The system of claim 10, wherein, prior to detecting the decoding failure, the controller is to store, in the virtual wordline, information that identifies the previous physical location of the data.

12. The system of claim 11, wherein, prior to detecting the decoding failure, the controller is to perform a read refresh operation on the previous physical location after storing the information in the virtual wordline.

13. The system of claim 9, wherein, to perform the read operation, the controller is to:
read a data frame from the previous physical location;
determine a logical block address (LBA) based on the data frame;
determine that a block, including the previous physical location, has not been overwritten based on the LBA; and
perform the read operation, using the second physical address, to obtain the data from the previous physical location based on determining that the block has not been overwritten.

14. The system of claim 13, wherein, to perform the read operation, the controller is to:
perform a comparison using the LBA and an LBA associated with a current physical location of the data; and
determining that the block has not been overwritten based on performing the comparison using the LBA and the LBA associated with the current physical location of the data.

15. A non-transitory computer-readable medium storing a set of instructions, the set of instructions comprising:
one or more instructions that, when executed by one or more processors of a controller, cause the controller to:
detect a decoding failure associated with data obtained, using a first physical address, from a current physical location of a non-volatile memory device, wherein the data is from a block of the non-volatile memory device;
determine that the block is a garbage collection block;
determine a second physical address of a previous physical location of the data, wherein the second physical address is determined using information from a virtual wordline of the garbage collection block; and
perform a read operation using the second physical address.

16. The non-transitory computer-readable medium of claim 15, wherein the data is obtained based on a read retry operation associated with the physical address.

17. The non-transitory computer-readable medium of claim 15, wherein the one or more instructions cause the controller to:
determine the virtual wordline using a logical unit number, a block number, and a page number, wherein the logical unit number, the block number, and the page number are identified by the first physical address.

18. The non-transitory computer-readable medium of claim 15, wherein the previous physical location is included in a block, and wherein the one or more instructions, that cause the controller to perform the read operation, cause the controller to:
determine whether additional block has been overwritten; and
perform the read operation, using the second physical address, to obtain the data from the previous physical location based on determining whether the block has been overwritten.

19. The non-transitory computer-readable medium of claim 15, wherein, prior to detecting the decoding failure, the one or more instructions cause the controller to:
store the information, in the virtual wordline, to identify the previous physical location of the data.

20. The non-transitory computer-readable medium of claim 15, wherein, prior to detecting the decoding failure, the one or more instructions cause the controller to:
perform a read refresh operation on the previous physical location after storing the information in the virtual wordline, to identify the previous physical location of the data.
